(19) United States
(12) Patent Application Publication
(10) Pub. No.: US 2025/0293165 A1
(43) Pub. Date: Sep. 18, 2025

(54) SEMICONDUCTOR DEVICE

(71) Applicant: SAMSUNG ELECTRONICS CO., LTD., SUWON-SI (KR)

(72) Inventors: KYUNGSOO LEE, SUWON-SI (KR); HORANG JANG, SUWON-SI (KR); JUNHO HUH, SUWON-SI (KR)

(21) Appl. No.: 19/064,834

(22) Filed: Feb. 27, 2025

(30) Foreign Application Priority Data
Mar. 14, 2024 (KR) 10-2024-0035987
Aug. 20, 2024 (KR) 10-2024-0111618

(51) Int. Cl. H01L 23/538; G06F 13/40; H01L 25/18

(52) U.S. Cl. CPC H01L 23/5381; G06F 13/4031; H01L 25/18

(57) ABSTRACT

A semiconductor device integrates a series of chiplet dies, each configurable as individual semiconductor chips, mounted on an interposer. Each chiplet die is equipped with a die-to-die interface enabling connectivity amongst them. The die-to-die interface in each chiplet includes a first connection module within a first chiplet die, having multiple first modules, and a second connection module within a second chiplet die, having multiple second modules. A selection circuit is used select specific second modules that align with corresponding first modules in the first connection module.

### CROSS-REFERENCE TO RELATED APPLICATION

This patent application claims priority under 35 U.S.C. § 119 to Korean Patent Application Nos. 10-2024-0035987, filed on Mar. 14, 2024, and 10-2024-0111618, filed on Aug. 20, 2024, in the Korean Intellectual Property Office, the disclosures of which are incorporated by reference in their entireties herein.

### 1. TECHNICAL FIELD

The inventive concept is directed to a semiconductor device. More particularly, the inventive concept is directed to a die-to-die interface between chiplet dies of the semiconductor device.

### 2. DISCUSSION OF RELATED ART

An electronic device configured to process data may perform various operations by accessing a memory. For example, the electronic device may process data read from the memory or may write data into the memory. Due to the performance and functionality needs of a system, it may include various electronic devices that communicate via links that provide high bandwidth and low latency.

A chiplet die, commonly referred to simply as a chiplet, is a smaller, modular semiconductor component that can be used in combination with other chiplets to form a larger, more complex processor or system. A system-in-package (SIP) may use a chiplet-based architecture that combines multiple dedicated small dies into a single package. The performance of the system may depend not only on the operating speed of each chiplet, but also on the communication efficiency and access time between the chiplets.

An issue arises from power constraints limiting the routing lengths for connections between chiplets. Given that the interfaces for these interconnections are fixed in position, if the routing length exceeds what is feasible, it renders the connection between chiplets impossible. As a result, this necessitates the creation of new chiplets with interface positions that accommodate the required routing lengths.

Creating new chiplets with tailored interface positions to accommodate specific routing lengths introduces several disadvantages, including increased costs and development time, which can delay product launches. It also complicates supply chain logistics and reduces system scalability by necessitating multiple specialized designs. Furthermore, this approach is resource-intensive, demanding significant financial, material, and human resources, making it less efficient for scenarios where cost, speed, and flexibility is important.

### SUMMARY

Embodiments of the present inventive concept may provide an interface structure for chiplet dies that is not limited by the design and size of existing chiplet dies to increase efficiency, and a semiconductor device including the same.

According to an aspect of the inventive concept, there is provided a semiconductor device including a plurality of chiplet dies and an interposer. The chiplet dies are configurable as semiconductor chips. The chiplet dies are mounted on the interposer. The plurality of chiplet dies each include a die-to-die interface for being connected to each other. The die-to-die interface includes a first connection module included in a first chiplet die among the chiplet dies, a second connection module included in a second chiplet die among the chiplet dies and a selection circuit. The first connection module includes a plurality of first modules and the second connection module includes a plurality of second modules. The selection circuit is configured to select one of the second modules that aligns with a corresponding one of the first modules.

According to another aspect of the inventive concept, there is provided a semiconductor device including a first chiplet die and a second chiplet die. The first chiplet die includes a first die-to-die interface, and a second chiplet die including a second die-to-die interface. The first chiplet die and the second chiplet die are adjacent to each other. Lengths of surfaces where the first chiplet die and the second chiplet die are adjacent to each other are different. The first die-to-die interface includes N modules for connecting to the second die, the second die-to-die interface includes M modules for connecting to the first die, N is different value from M, and N and M are natural numbers. The second die-to-die interface includes a selection circuit configured to select one or more of the M modules that align with corresponding ones of the N modules.

According to another aspect of the inventive concept, there is provided a semiconductor device including a plurality of chiplet dies that are configurable semiconductor chips, and an interposer on which the plurality of chiplet dies are mounted, wherein the plurality of chiplet dies each include a die-to-die interface for being connected to each other, a first die-to-die interface included in a first chiplet die includes N modules, and a second die-to-die interface included in a second chiplet die includes M modules, wherein the N modules are configured to connect all of the N modules to another die, and the M modules are configured to connect only some of the M modules among the M modules to another die, and N and M are natural numbers.

### BRIEF DESCRIPTION OF THE DRAWINGS

Embodiments will be more clearly understood from the following detailed description taken in conjunction with the accompanying drawings in which:

FIG. 1 is a perspective view illustrating a semiconductor device according to an embodiment;

FIGS. 2A to 2C are diagrams for explaining a die-to-die connection structure according to a comparative example;

FIG. 3A is a diagram for explaining the connection of dies according to a comparative example, and FIG. 3B is a diagram to explain the connection of dies according to an embodiment;

FIGS. 4A and 4B are diagrams for explaining a connection structure of dies according to an embodiment;

FIGS. 5A and 5B are for explaining a connection of dies according to an embodiment;

FIGS. 6A and 6B are block diagrams for explaining an example of a die-to-die interface according to an embodiment;

FIGS. 7A and 7B are block diagrams for explaining an example of a die-to-die interface according to an embodiment.

FIGS. 8A and 8B are block diagrams for explaining an example of a die-to-die interface according to an embodiment; and

FIG. 9 is a block diagram of a system for explaining an electronic device including a D2D interface according to embodiments.

### DETAILED DESCRIPTION

At least one embodiment pertains to a semiconductor device that integrates a series of chiplet dies, each configurable as individual semiconductor chips, mounted on an interposer. Each chiplet die is equipped with a die-to-die interface enabling connectivity amongst them. The die-to-die interface in each chiplet comprises two connection modules: a first connection module within a first chiplet die, consisting of multiple first modules, and a second connection module within a second chiplet die, containing multiple second modules. A selection circuit may select specific second modules that align with corresponding first modules in the first connection module. This configuration facilitates precise inter-chiplet communication and optimizes the device's modular architecture for enhanced performance and scalability in complex semiconductor systems.

Hereinafter, various embodiments are described with reference to the accompanying drawings.

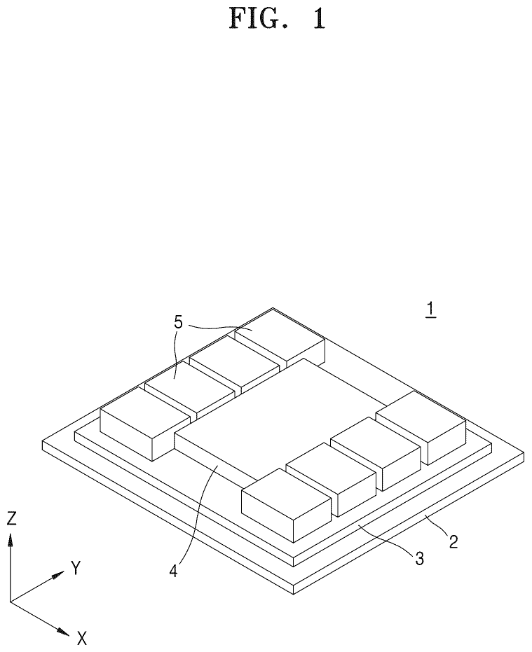

FIG. 1 is a perspective view illustrating a semiconductor device 1 according to an embodiment.

Referring to FIG. 1, the semiconductor device 1 may include a substrate 2, an interposer 3, a first semiconductor chip 4, and at least one second semiconductor chip 5.

The substrate 2 may include a printed circuit board (PCB), a ceramic substrate, a glass substrate, a tape wiring board, etc. According to an example, the substrate 2 may be a large-area package substrate for mounting the high-performance first semiconductor chip 4 and the high-performance second semiconductor chip 5. For example, the substrate 2 may have a planar shape, such as a square or a rectangle, and a horizontal width and/or a vertical width of the substrate 2 may be 40 millimeters (mm) or more.

The interposer 3 may be placed on an upper surface of the substrate 2. The upper surface of the substrate 2 may face a lower surface of the interposer 3. According to an example, the interposer 3 may include a silicon interposer substrate including a through silicon via (TSV), but is not limited thereto.

The first semiconductor chip 4 and the second semiconductor chip 5 according to an example may be mounted on the interposer 3. The first semiconductor chip 4 and the second semiconductor chip 5 may be placed adjacent to each other on an upper surface of the interposer 3. For example, the second semiconductor chip 5 may be placed around the first semiconductor chip 4. The number of the first and second semiconductor chips 4 and 5 is not limited to the number shown in the drawing, and dummy chips may be additionally placed.

According to an example, the first semiconductor chip 4 may be a logic semiconductor chip. For example, the first semiconductor chip (4) may include an application processor (AP) such as a Central Processing Unit (CPU), a Graphics Processing Unit (GPU), a Field-Programmable Gate Array (FPGA), a digital signal processor, an encryption processor, a microprocessor, a microcontroller, an Application-Specific IC (ASIC), etc., but is not limited thereto.

According to an example, the second semiconductor chip 5 may include a memory semiconductor chip. For example, the second semiconductor chip 5 may include a volatile memory, such as a dynamic random access memory (DRAM) or a static random access memory (SRAM), include a nonvolatile memory, such as a flash memory, a phase-change random access memory (PRAM), a magnetoresistive random access memory (MRAM), a ferroelectric random access memory (FeRAM), or a resistive random access memory (RRAM), or a high-performance memory device, such as a high bandwidth memory (HBM), a hybrid memory cubic (HMC), etc.

For example, the first semiconductor chip 4 may include an ASIC, such as a GPU, and the second semiconductor chip 5 may include a stack memory, such as an HBM. The stack memory may be configured with multiple integrated circuits stacked on top of one another. The stacked integrated circuits may be electrically connected via through-silicon vias (TSVs).

According to an embodiment, the first semiconductor chip 4 and/or the second semiconductor chip 5 are semiconductor chiplet dies. The chiplet die may be a unit that constitutes a semiconductor die including one or more cores. The chiplet dies may be assembled to function as one semiconductor die. According to an example, each of the chiplet dies that function as one semiconductor die may be individualized and may be configured as an individualized upper package. The individualized upper packages may be mounted on a lower module substrate, and the individualized upper packages may be electrically connected by the lower module substrate. As the individualized upper packages are mounted on the lower module substrate, the semiconductor package module including the lower module substrate may be configured as a package capable of performing the function of one semiconductor die.

According to an example, a chiplet die may denote individual chips that constitute an Multi-Chip Module (MCM). For example, the chiplet die may include at least one of an input/output circuit, an analog circuit, a memory circuit, and a serial-to-parallel conversion circuit. Alternatively, the chiplet die may include at least one of a CPU, a GPU, and an FPGA. The number of chiplet dies mounted on the interposer 3 is not particularly limited, and a greater number of chiplets than those shown in the drawing may be mounted on the interposer 3.

The chiplet dies according to an example may be coupled to each other by one or more die-to-die (D2D) interfaces. In addition, the chiplet dies may be coupled to one or more interposers 3, which may be configured to enable communication between the chiplet dies and other components (e.g., acting as a bridge or conduit that allows electrical signals to pass between internal and external elements).

The chiplet dies according to an embodiment may include adjustable modules that enable interconnection between various chiplet dies when a chiplet design and a chip size are specified. The die-to-die interface according to an embodiment may overcome limitations in existing chiplet design by equipping multiple modules and interfacing with other dies using a selected combination of these modules.

Hereinafter, the configuration of the die-to-die interface according to an embodiment will be described in more detail. Hereinafter, the terms ‘chiplet die’ and ‘die’ may be used interchangeably. The descriptions pertaining to the die described below may be applied to the chiplet die described with reference to FIG. 1.

According to an embodiment, the configuration of the D2D interface of the chiplet die may be implemented to increase the number of HBMs connected to the GPU within a structure that includes both the GPU and an HBM. According to an embodiment, the configuration of the D2D interface of the chiplet die may also be implemented to increase the reusability of a die in a chiplet structure.

The semiconductor device 1 according to an example may be a semiconductor package and may be a 2.5D package.

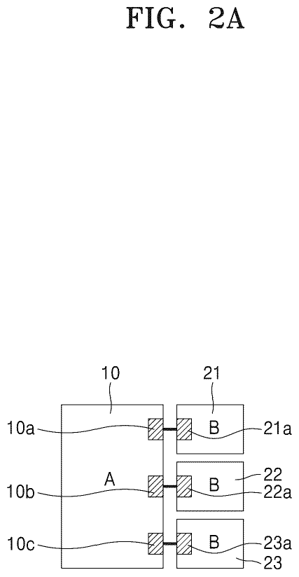

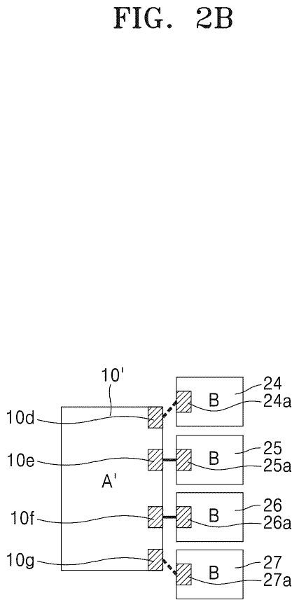

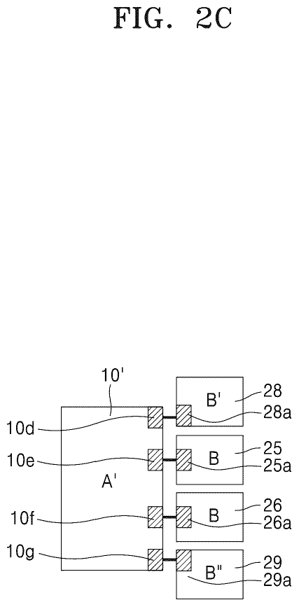

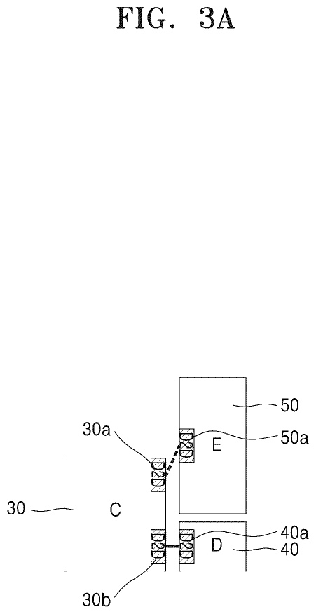

FIGS. 2A to 2C are diagrams to explain a die-to-die connection structure according to a comparative example.

Referring to FIG. 2A, a die 10 of A and dies 21, 22, and 23 of B are arranged side by side, and die-to-die interfaces 10a, 10b, 10c, 21a, 22a, and 23a for connecting the die 10 of A and the dies 21, 22, and 23 of B, respectively, are illustrated. According to an example, the die 10 of A include the die-to-die interfaces 10a, 10b, and 10c for connecting to the dies 21, 22, and 23 of B. According to an example, each of the dies 21, 22, and 23 of B include die-to-die interfaces 21a, 22a, and 23a for connecting to the die 10 of A. According to an example, the die-to-die interface is a D2D PHY, but is not limited thereto.

A die-to-die interconnection in a chiplet structure may be constrained by routing length. This denotes that a straight-line distance between interconnecting PHYs in each die is constrained, and if the straight-line distance exceeds the routing length, there may be a situation in which connection between dies is impossible. Due to the fixed position of the D2D PHY in a conventional chip, limitations in configuration may arise when reusing the same chip in a chiplet.

Referring to FIG. 2A, when connecting two or more dies to each other, there may be a constraint that a 2 mm routing length needs to be satisfied. Accordingly, when two or more dies are connected to each other as in FIG. 2A, the die-to-die interfaces included in each die may be arranged by aligning their central axes with each other. The arrangement of the dies in FIG. 2A according to an example may be an arrangement according to the chiplet design.

In the present inventive concept, the meaning of modules or interfaces being aligned may be the same as the meaning of being aligned to a die-to-die interface included in another die, and aligning modules or interfaces may denote arranging or selecting modules that are positioned at the same height or width in an X-axis or Y-axis direction to correspond to connecting modules included in a die-to-die interface to be connected. That is, the meaning of aligning may denote selecting a part that positionally corresponds to a D2D interface in a corresponding chip in a structure of a chiplet.

Referring to FIG. 2A, it may be observed that the D2D interface 10a included in the die 10 of A and the D2D interface 21a included in the die 21 of B are aligned, the D2D interface 10b included in the die 10 of A and the D2D interface 22a included in the die 22 of B are aligned, and the D2D interface 10c included in the die 10 of A and the D2D interface 23a included in the die 23 of B are aligned.

Referring to FIG. 2B, a die 10′ of A′ and dies 24, 25, 26, and 27 of B are arranged side by side, and die-to-die interfaces 10d, 10e, 10f, 10g, 24a, 25a, 26a, and 27a for connecting the die 10′ of A′ and the dies 24, 25, 26, and 27 of B, respectively, are shown. In the chiplet design of FIG. 2B, it is assumed that the new die 10′ of A′ having the same size as the die 10 of A of FIG. 2A but having a different die-to-die interface structure is manufactured, while the die of B of FIG. 2A is reused.

In the chiplet design according to FIG. 2B, a case is shown where the number of the dies of B corresponding to one side of the die 10′ of A′ is increased to 4. In this case, the arrangement positions of die-to-die interfaces 24a, 25a, 26a, and 27a included in dies 24, 25, 26, and 27 of B may be the central portions of each die as in FIG. 2A. Accordingly, the die-to-die interfaces 10d and 10g included in die 10′ of A′ having the same side length as die 10 of A of FIG. 2A and the die-to-die interfaces 24a and 27a included in dies 24 and 27 of B may not be aligned in a straight line. However, if the die-to-die interfaces 10d and 10g and the die-to-die interfaces 24a and 27a are not aligned in a straight line, it is difficult to solve the constraints of the routing length as described above.

To align these components in a straight line, a length of the longer side of the die 10′ of A′ may be increased in length. However, in current semiconductor processes, the length of each die's longer side is typically restricted to a maximum of 33 mm due to limitations of photolithography. However, since the length of the longer side of the die 10′ of A′ may already be at its maximum, aligning the interfaces in a straight line might not be feasible, even if die 10′ of A′ is newly manufactured. This could result in failure to meet the 2 mm routing length requirement. In addition, the need to manufacture a new die 10′ of A′ could pose further complications.

Alternatively, the dies 24, 25, 26, and 27 of B may be manufactured smaller, but this may also require the manufacture of a new die, and it may not be easy to manufacture a smaller die. Alternatively, while increase the routing length is possible, this may violate design rules and lead to higher power consumption.

In the chiplet design according to FIG. 2C, the same chiplet design as the chiplet design of FIG. 2B is disclosed, but an example of newly manufacturing a corresponding die for die-to-die alignment in the chiplet design is illustrated.

Referring to FIG. 2C, a configuration of the die 10′ of A′ and the die-to-die interfaces 10d, 10e, 10f, and 10g included in the die 10′ of A′ are the same as in FIG. 2B, and a die 28 of B′ and a die-to-die interface 28a included in the die 28 of B′, and a die 29 of B″ and a die-to-die interface 29a included in the die 29 of B″ may be different from FIG. 2B.

Referring to FIG. 2C, the position of the die-to-die interface 28a included in the die 28 of B′ may be changed to align with the die-to-die interface 10d included in the die 10′ of A′, and the position of the die-to-die interface 29a included in the die 29 of B″ may be changed to align with the die-to-die interface 10g included in the die 10′ of A′.

Referring to FIGS. 2A to 2C, to facilitate connections between dies by changing the chiplet design, the fixed positions of the die-to-die interfaces on previously manufactured chiplet may necessitate the manufacture of a new chiplet for proper alignment. However, this may limit the diversity of designs of the chiplet design or impose additional costs due to the need for producing more chiplets.

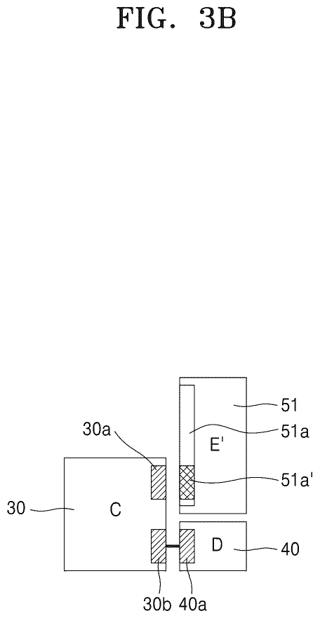

FIG. 3A is a diagram to explain the connection of dies according to a comparative example, and FIG. 3B is a diagram to explain the connection of dies according to an embodiment.

Referring to FIG. 3A, a structure is shown in which a die 30 of C, a die 40 of D, and a die 50 of E are arranged according to a chiplet design. Each of the dies may include a die-to-die interface. The die 30 of C includes die-to-die interfaces 30a and 30b, the die 40 of D includes a die-to-die interface 40a, and the die 50 of E includes a die-to-die interface 50a.

Referring to FIG. 3A, the die-to-die interface 30b of the die 30 of C and the die-to-die interface 40a of the die 40 of D are already aligned, thus there is no problem in connecting them. However, the die-to-die interface 30a of the die 30 of C and the die-to-die interface 50a of the die 50 of E are not aligned, which may lead to exceeding the 2 mm routing length constraint. If the die 30 of C, the die 40 of D, and the die 50 of E are pre-existing chiplet dies with fixed die-to-die interface positions, this setup may pose limitations when attempting to integrate them into a single chiplet. Overcoming these limitations typically requires the manufacturing of a new chiplet die. However, according to an embodiment, a chiplet die structure is proposed that allows for connection to various dies without the need to manufacture a new chiplet die.

Referring to FIG. 3B, the die 30 of C, the die 40 of D, and a die 51 of E′ are provided to illustrate the embodiment.

Because the configurations of the die 30 of C and the die 40 of D are the same as the descriptions given with reference to FIG. 3A, descriptions already given are omitted. The die 51 of E′ includes a die-to-die interface 51a. The die-to-die interface 51a of the die 51 of E′ illustrated in FIG. 3B is different from the die-to-die interface 50a of the die 50 of E of FIG. 3A. The die-to-die interface 51a according to an example includes a region 51a′ that is aligned with the die-to-die interface 30a of the adjacent die 30 of C. According to an embodiment, the inclusion of a die-to-die interface that may select variably aligned positions, as opposed to one fixed in place, eliminates the need to manufacture a new chiplet die according to the arrangement structure of the chiplet die. This allows for the provision of a more efficient chiplet die. According to an embodiment, additional design may be performed from the viewpoint of a D2D configuration that connects dies to dies, and a chiplet die may be configured by selecting only necessary modules among a plurality of modules.

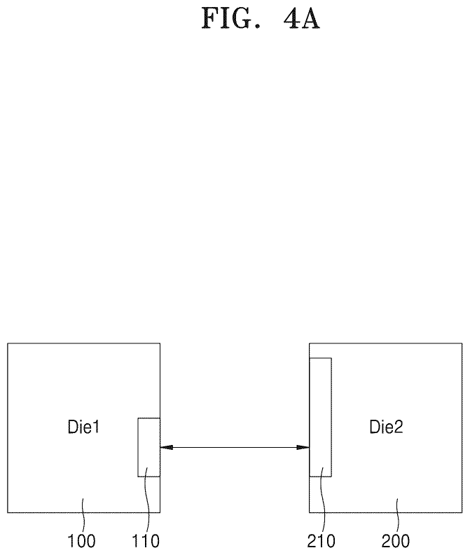

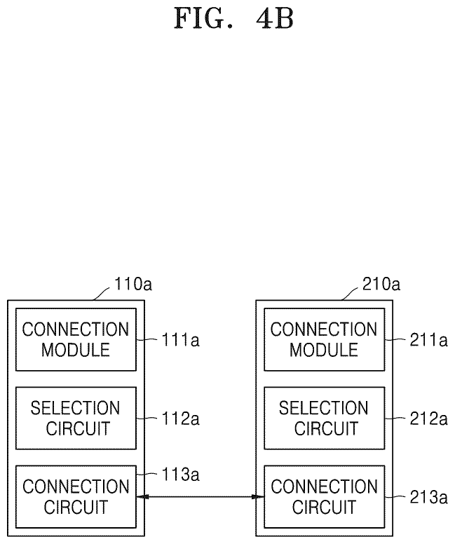

FIG. 4A and FIG. 4B are diagrams to explain a connection structure of dies according to an embodiment.

Referring to FIG. 4A, a first die 100 and a second die 200 are shown. According to an example, the first die 100 and the second die 200 are arranged at positions that are adjacent to each other. Further, it is assumed that they are dies that are coupled to each other. According to an example, the first die 100 and the second die 200 may be chiplet dies.

The first die 100 may include a first die-to-die interface 110, and the second die 200 may include a second die-to-die interface 210. The first die-to-die interface 110 and the second die-to-die interface 210 may connect the first die 100 and the second die 200. In the present embodiment, the meaning that ‘may be connected’ may denote being communicatively connected for information transfer between dies.

In the diagram of FIG. 4A, for convenience of explanation, the first die 100 and the second die 200 are illustrated as blocks of the same size, but lengths of surfaces where the first die 100 and the second die 200 contact each other may be different.

Referring to FIG. 4B, a block diagram is illustrated to explain components included in each of the first die-to-die interface 110a and the second die-to-die interface 210a.

Referring to FIG. 4B, the first die-to-die interface 110a may include a connection module 111a, a selection circuit 112a, and a connection circuit 113a, and the second die-to-die interface 210a may include a connection module 211a, a selection circuit 212a, and a connection circuit 213a.

According to an example, the connection modules 111a and 211a may include several modules equal to or greater than the number of bits that each die may connect to other dies. According to an example, the connection module 111a included in a first die-to-die interface 110a of the first die 100 may include N modules that may be connected to other dies. According to an example, the connection module 111a included in the first die-to-die interface 110a may be a fixed module. In the present embodiment, the fixed module may denote a module that connects to another die by using all of the multiple modules included in the connection module 111a. According to an example, the connection module 211a included in the second die-to-die interface 210a of the second die 200 may include M modules that may be connected to another die. According to an example, the connection module 211a included in the second die-to-die interface 210a may be a variable module. In the present embodiment, the variable module may denote a module that connects to another die by using only some of the multiple modules included in the connection module 211a. According to an example, both N and M are natural numbers greater than or equal to 1. According to an example, the first die 100 may include a fixed module, and the second die 200 may include a variable module.

According to an example, the selection circuits 112a and 212a may be circuits for selecting some of the modules included in the connection modules 111a and 211a. As described above, if the connection module 111a is a fixed module, because all of the modules included in the connection module 111a are used, the selection circuit 112a connected to the connection module 111a may be omitted. If the connection module 211a is a variable module, the selection circuit 212a for selecting some of the modules included in the connection module 211a may be provided. The selection circuit 212a according to an example may include a multiplexer for selecting and outputting one of a plurality of inputs but is not limited thereto.

The connection circuits 113a and 213a may include an interface for connecting an output of the connection module 111a and the selection circuits 112a and 212a to an adjacent die. According to an example, the connection circuits 113a and 213a may include a physical interface. According to an example, the first die 100 and the second die 200 that are arranged adjacent to each other may be communicatively connected through the connection circuits 113a and 213a. According to an example, the connection circuits 113a and 213a may support a Universal Chiplet Interconnect express (UCIe) protocol for communication between the first die 100 and the second die 200. According to an example, the connection circuits 113a and 213a may include a PHY or one of a link, a controller, and an adapter.

In the embodiment, a case is described where one of the first die-to-die interface 110a and the adjacent second die-to-die interface 210a is a fixed module and the other is a variable module, but both the adjacent first die-to-die interface 110a and the second die-to-die interface 210a may be variable modules. According to an embodiment, the second die 200 including a variable module may be a die having sufficient free space. According to an example, the second die 200 including the variable module may be an HBM die. According to an example, the second die 200 including the variable module may be a die including a certain percentage or more of free space. According to an example, the second die 200 including the variable module may be a die having a free space of 30% or more.

In addition, in the embodiment, an example in which the die-to-die interface is formed adjacent to one side of the die is illustrated, but the die-to-die interface may be formed adjacent to the other side of the die or may be formed on two or more sides of the die, respectively.

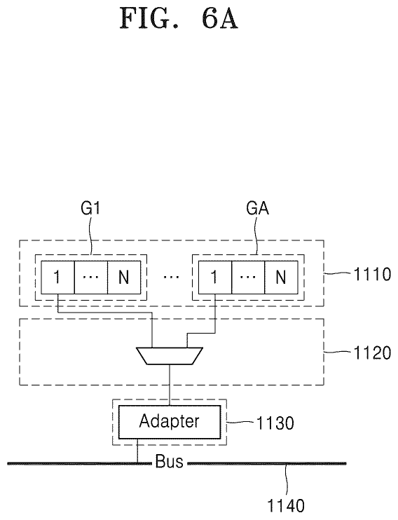

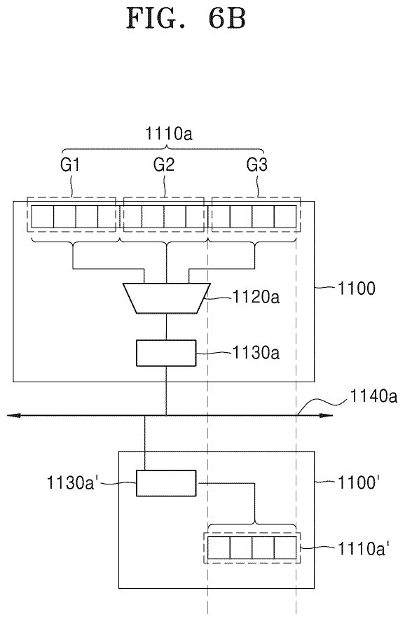

According to an example, the connection module 211a may include a plurality of D2D interface groups, and an actual D2D interface group used among the D2D interface group may be selected by the selection circuit 212a for routing alignment. The D2D interface group may be a single copy or a group that shares a portion with each other. A method of forming a group using a plurality of modules will be described later with reference to FIG. 6A and below.

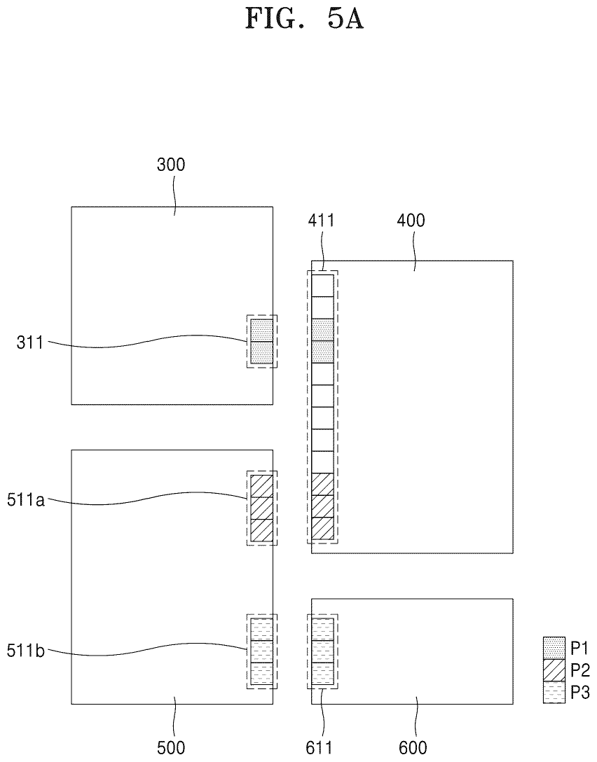

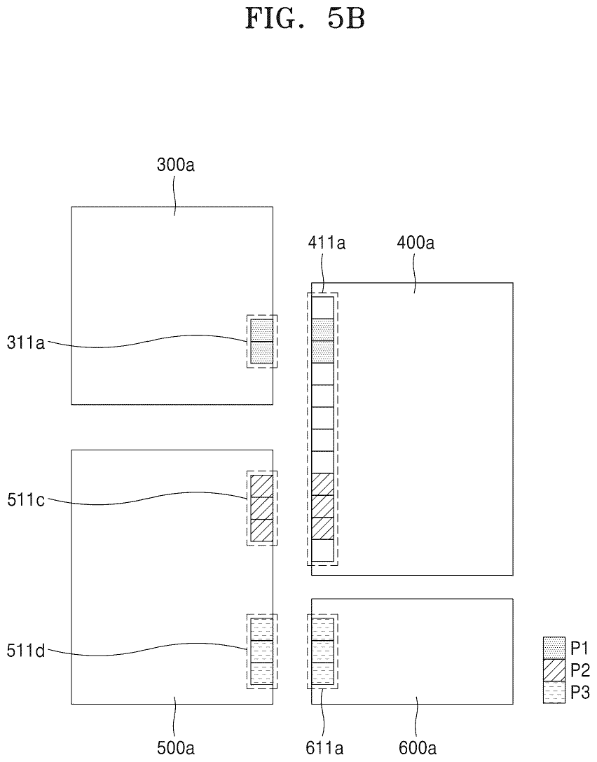

FIGS. 5A and 5B are diagrams to explain a connection of dies according to an embodiment.

Referring to FIG. 5A, four dies and a plurality of connection modules included in each of the dies are illustrated. In FIGS. 5A and 5B, for convenience of explanation, only the connection modules among components included in the die-to-die interface are illustrated.

According to an example, a third die 300, a fourth die 400, a fifth die 500, and a sixth die 600 are arranged respectively according to a chiplet design.

The third die 300 may include a first connection module 311, the fourth die 400 may include a second connection module 411, the fifth die 500 may include third connection modules 511a and 511b, and the sixth die 600 may include a fourth connection module 611. The first connection module 311 of the third die 300 may be a fixed module for connection with the fourth die 400. According to an example, the second connection module 411 of the fourth die 400 is a variable module for connection with the third die 300 and the fifth die 500. The third connection modules 511a and 511b of the fifth die 500 may be fixed modules for connection with the fourth die 400 and the sixth die 600. The fourth connection module 611 of the sixth die 600 may be a fixed module for connection with the fifth die 500.

According to an example, the fixed modules included in the third die 300, the fifth die 500, and the sixth die 600 may be used to align with the modules of the counterpart die by using all of the multiple modules included in the fixed modules.

Among the connection modules illustrated in FIG. 5A, modules filled with a pattern may denote modules selected for connection with the facing die, and white modules among the connection modules that are not filled with a pattern may denote modules that are not used for connection with the facing die. According to an example, the fixed modules may include only modules filled with patterns, and the variable modules may include both modules filled with patterns and white modules that are not filled with patterns.

As shown in FIG. 5A, modules having the same pattern included in different dies are illustrated as connection modules that are aligned with each other. According to an example, the connection module that is aligned with the first connection module 311 included in the third die 300 may be modules having a first pattern P1 among the second connection modules 411 included in the fourth die 400. According to an example, the connection module that is aligned with the third connection module 511a included in the fifth die 500 may be modules having a second pattern P2 among the second connection modules 411 included in the fourth die 400. The connection module aligned with the third connection module 511b included in the fifth die 500 may be a module having a third pattern P3 among the fourth connection modules 611 included in the sixth die 600.

In this way, in the case of the second connection module 411 including a variable module, connection between dies may be performed by selecting a module that is aligned with a connection module included in adjacent dies among multiple modules.

Referring to FIG. 5B, a third die 300a, a fourth die 400a, a fifth die 500a, and a sixth die 600a may be respectively arranged according to a chiplet design.

The third die 300a may include a first connection module 311a, the fourth die 400a may include a second connection module 411a, the fifth die 500a may include a third connection module 511c and 511d, and the sixth die 600a may include a fourth connection module 611a.

The configurations of the third die 300a, the fifth die 500a, and the sixth die 600a may correspond to the descriptions of the third die 300, the fifth die 500, and the sixth die 600 described above with reference to FIG. 5A, and thus, descriptions previously given are omitted.

According to an example, the position at which the fourth die 400a of FIG. 5B is arranged may be different from the position at which the fourth die 400 of FIG. 5A is arranged. The position at which the fourth die 400a of FIG. 5B is placed may be closer to the sixth die 600a than the position at which the fourth die 400 of FIG. 5A is positioned. In this case, because the position of the fourth die 400a has changed, the connection module aligned to the first connection module 311a of the third die 300a and the connection module aligned to the third connection module 511c of the fifth die 500a may be different compared to the case of FIG. 5A.

Referring to FIG. 5A and FIG. 5B, a module selected for alignment among the second connection modules 411a included in the fourth die 400a may vary depending on the arrangement position of the connection modules included in the adjacent die.

In a D2D interface according to an example, the number of modules required for connection with the adjacent die may be determined according to an amount of bandwidth used. For example, if one module covers a bandwidth of A GB/s and a required bandwidth between chips is B, the number of modules required for connection may be an integer C greater than B/A. According to a comparative example, a D2D interface includes C modules, but in the present embodiment, it may include D modules greater than C, and only C modules may be selected and used among the D modules.

FIGS. 6A and 6B are block diagrams to explain an example of a die-to-die interface according to an embodiment.

Referring to FIG. 6A, a configuration of a connection module 1110, a selection circuit 1120, a connection circuit 1130, and a bus 1140 is disclosed. According to an example, the configuration of the connection module 1110, the selection circuit 1120, and the connection circuit 1130 of FIG. 6A may correspond to the configuration of the connection module 111a, the selection circuit 112a, and the connection circuit 113a illustrated in FIG. 4B.

According to an example, the connection module 1110 may include a plurality of groups G1, . . . , GA. According to an example, A may be a natural number greater than or equal to 2. According to an example, each of the plurality of groups may include N modules required for D2D connection. According to an example, N may be a natural number greater than or equal to 2. That is, in this case, the total number of modules included in the connection module 1110 may be N*A. That is, the total number of modules included in the connection module 1110 may be an integer multiple of the number of modules included in each group. According to an example, each of the plurality of groups may include the same number of modules. According to an example, the number of modules included in the plurality of groups may correspond to the number of fixed modules included in a die to be connected.

The selection circuit 1120 may be connected to output terminals of the plurality of groups G1, . . . , GA. According to an example, the selection circuit 1120 may include one multiplexer. One multiplexer included in the selection circuit 1120 may select one of the plurality of groups G1, . . . , GA and output the selected group to the connection circuit 1130. According to an example, the selection circuit 1120 may select a group formed at a corresponding position among the plurality of groups G1, . . . , GA according to the position of the connection module included in the adjacent die.

The connection circuit 1130 may include an adapter but is not limited thereto. The connection circuit 1130 may be connected to the bus 1140 and may transmit information output from the selection circuit 1120 to another die.

FIG. 6B illustrates an embodiment of a die-to-die interface corresponding to FIG. 6A.

Referring to FIG. 6B, a first die-to-die interface 1100 including a variable module and a second die-to-die interface 1100′ including a fixed module are each disclosed. The first die-to-die interface 1100 may include a connection module 1110a, a selection circuit 1120a, and a connection circuit 1130a, and the second die-to-die interface 1100′ may include a connection module 1110a′ and a connection circuit 1130a′. The connection circuit 1130a of the first die-to-die interface 1100 and the connection circuit 1130a′ of the second die-to-die interface 1100′ may be connected via a bus 1140a.

According to an example, the connection module 1100a of the first die-to-die interface 1100 may include a plurality of groups G1, G2, and G3. Each of the plurality of groups G1, G2, and G3 may include four modules. According to an example, because the connection module 1100a may include a total of three groups, and each group may include four modules, the connection module 1100a may include a total of twelve modules. Here, the reason why the plurality of groups include four modules may be because the number of connection modules 1110a′ included in an adjacent die is four.

According to an example, the selection circuit 1120a may select a group that is aligned with the position of the connection module 2110a of the adjacent die. According to an example, the selection circuit 1120a may select the group G3 that is aligned with the location of the connection module 1110a′ and transmit the result of its selection to the connection circuit 1130a. In this way, the connection module 1110a may include a plurality of groups G1, G2, and G3, and may select and connect the group G3 that is aligned with an adjacent die among the plurality of groups G1, G2, and G3.

In some diagrams of the inventive concept, to explain the alignment of connection modules included in different dies, vertically extending dashed lines are used.

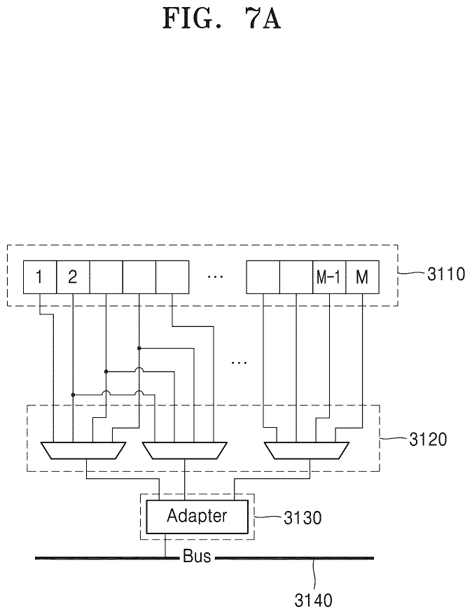

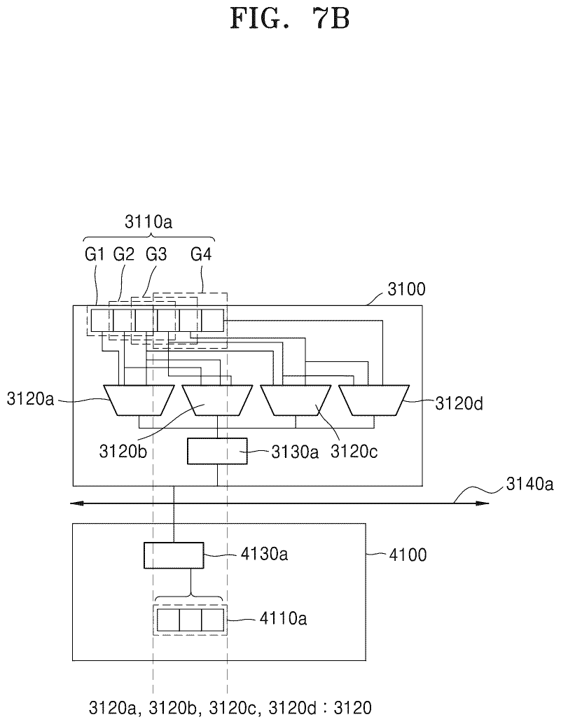

FIG. 7A and FIG. 7B are block diagrams illustrating an example of a die-to-die interface according to an embodiment.

Referring to FIG. 7A, the configuration of a connection module 3110, a selection circuit 3120, a connection circuit 3130, and a bus 3140 is shown. According to an example, the configuration of the connection module 3110, the selection circuit 3120, and the connection circuit 3130 of FIG. 7A may correspond to the configuration of the connection module, the selection circuit, and the connection circuit illustrated in FIG. 4B.

The connection module 3110 may include a plurality of modules. According to an example, the connection module 3110 may include M modules. M may be a natural number greater than or equal to 2.

The selection circuit 3120 may include a plurality of multiplexers. According to an example, each of the plurality of multiplexers may select a starting module from among the plurality of modules included in the connection module 3110 and configure one group consisting of N modules including the corresponding module. In the example of FIG. 7A, N=4.

The number of multiplexers included in the selection circuit 3120 according to the example may be M−N+1. At this time, M may denote the number of multiple modules included in the connection module 3110, and N may be the number of modules included in a die adjacent to the corresponding die and to be connected. M and N may be natural numbers. For example, M may have a value greater than N.

In the case of the embodiment of FIG. 7A, groups may be sequentially formed among the M modules included in the connection module 3110, and a plurality of multiplexers may be disclosed for selecting each group. The difference between the embodiment of FIG. 7A and that of FIG. 6A is that in FIG. 7A, groups are sequentially formed for modules that are formed sequentially, but in the case of FIG. 6A, groups are formed for copies that are copies of corresponding modules. That is, in the case of FIG. 6A, the configurations of modules included in multiple groups are completely identical, but in the case of FIG. 7A, the configurations of modules included in multiple groups may be different.

FIG. 7B illustrates an embodiment corresponding to the die-to-die interface of FIG. 7A.

Referring to FIG. 7B, a first die-to-die interface 3100 and a second die-to-die interface 4100 are illustrated. The first die-to-die interface 3100 may include a connection module 3110a, a selection circuit 3120, and a connection circuit 3130a, and the second die-to-die interface 4100 may include a connection module 4110a and a connection circuit 4130a. The first die-to-die interface 3100 and the second die-to-die interface 4100 may be connected through a bus 3140a based on the connection circuits 3130a and 4130a included in each of the first die-to-die interface 3100 and the second die-to-die interface 4100.

The connection module 3110a of the first die-to-die interface 3100 may include a plurality of groups G1, G2, G3, and G4. The group of FIG. 7B may be different from the group of FIG. 6B in that the groups formed in FIG. 6B do not have overlapping modules between the groups, but the groups of FIG. 7B may have overlapping modules between the groups. Each of the groups G1, G2, G3, and G4 of FIG. 7B may be groups formed by sequentially cutting three modules out of the plurality of modules. The first group G1 according to an example may be a group formed by grouping the first module, the second module, and the third module among the six modules of the connection module 3110a. The second group G2 according to an example may be a group formed by grouping the second module, the third module, and the fourth module among the six modules of the connection module 3110a. The third group G3 according to an example may be a group formed by grouping the third module, the fourth module, and the fifth module among the six modules of the connection module 3110a. The fourth group G4 according to an example may be a group formed by grouping the fourth module, the fifth module, and the sixth module among the six modules of the connection module 3110a. Here, the reason why multiple modules are sequentially formed by cutting or dividing them into threes may be because the number of connection modules 4110a included in adjacent dies is three. If this case is substituted into FIG. 7A, it may be the case when M=6 and N=3.

The selection circuit 3120 for selecting one of the four groups G1, G2, G3, and G4 may be connected to the connection module 3110a. The selection circuit 3120 may include a first multiplexer 3120a, a second multiplexer 3120b, a third multiplexer 3120c, and a fourth multiplexer 3120d. The first multiplexer 3120a may be connected to multiple modules included in the first group G1 to select the first group G1. The second multiplexer 3120b may be connected to a plurality of modules included in the second group G2 to select the second group G2. The third multiplexer 3120c may be connected to a plurality of modules included in the third group G3 to select the third group G3. The fourth multiplexer 3120d may be connected to a plurality of modules included in the fourth group G4 to select the fourth group G4. The selection circuit 3120 includes a plurality of multiplexers and may select a multiplexer for selecting a connection module corresponding to the connection module 4110a of an adjacent die and output the corresponding result.

Referring to FIG. 7B, because the group of the first die-to-die interface 3100 aligned to the connection module 4110a included in the second die-to-die interface 4100 is the fourth group G4, to select the fourth group G4, the selection circuit 3120 may transfer an output of the fourth multiplexer 3120d to the connection circuit 3130a.

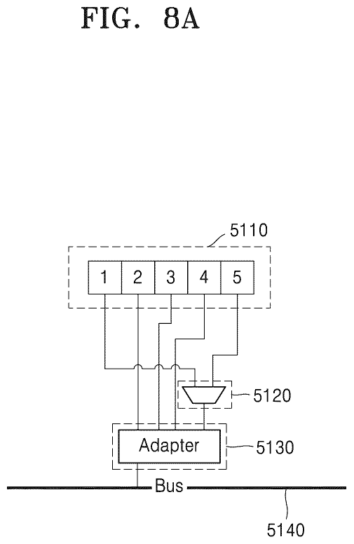

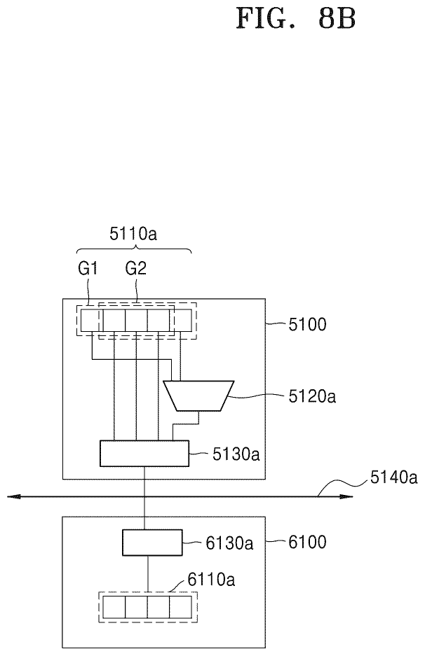

FIG. 8A and FIG. 8B are block diagrams illustrating an example of a die-to-die interface according to an embodiment.

Referring to FIG. 8A, the configuration of a connection module 5110, a selection circuit 5120, a connection circuit 5130, and a bus 5140 is shown. According to an example, the configuration of the connection module 5110, the selection circuit 5120, and the connection circuit 5130 of FIG. 8A may correspond to the configuration of the connection module, the selection circuit, and the connection circuit illustrated in FIG. 4B.

Referring to FIG. 8A, the connection module 5110 may include M modules. According to an example, the selection circuit 5120 may include one multiplexer. In the embodiment of FIG. 8A, M may be 5.

According to an example, a multiplexer included in the selection circuit 5120 may be connected to only some of the plurality of modules included in the connection module 5110. Referring to FIG. 8A, only the first module and the fifth module among the plurality of modules included in the connection module 5110 may be connected to the multiplexer included in the selection circuit 5120.

According to an embodiment, some modules within the connection module 5110 may be fixed for use, independent of the selection circuit. Additionally, a selection circuit 5120, which determines which of these fixed modules to utilize may be disclosed. According to an embodiment, this method may be efficient in terms of cost and area by reducing the number of multiplexers.

According to an embodiment, the configuration method for the selection circuit may be applied when the relationship between the number M of modules in the connection module 5110 and the number N of modules required by the die to be connected satisfies the condition: N>M/2.

At this time, fixed ones among the multiple modules included in the connection module 5110 may correspond to 2N-M modules located in the middle.

According to an embodiment, in the case when groups formed by the multiple modules included in the connection module 5110 share some modules in a fixed order, the shared modules may be fixed and directly connected to the connection circuit 5130, and the remaining modules may be selected and output through the selection circuit 5120.

Referring to FIG. 8A, FIG. 8A is a diagram assuming M=5 and N=4. In the connection module 5110 of FIG. 8A, the number of modules to be fixed is 3.

Referring to FIG. 8B, an embodiment corresponding to the die-to-die interface of FIG. 8A is shown.

Referring to FIG. 8B, a first die-to-die interface 5100 and a second die-to-die interface 6100 are shown. The first die-to-die interface 5100 may include a connection module 5110a, a selection circuit 5120a, and a connection circuit 5130a, and the second die-to-die interface 6100 may include a connection module 6110a and a connection circuit 6130a. The first die-to-die interface 5100 and the second die-to-die interface 6100 may be connected via a bus 5140a based on the connection circuits 5130a and 6130a included in the first die-to-die interface 5100 and the second die-to-die interface 6100, respectively.

According to an embodiment, the connection module 5110a of the first die-to-die interface 5100 may include multiple groups G1 and G2. The group of FIG. 8B differs from the group of FIG. 6B in that the groups formed in FIG. 6B do not have overlapping modules between the groups, but in the groups of FIG. 8B, there are modules that overlap each other between the groups. The groups G1 and G2 of FIG. 8B may be groups formed by sequentially cutting four modules out of a plurality of modules. Here, the reason why the groups are formed by sequentially cutting four modules out of a plurality of modules may be because the number of connection modules 6110a included in the adjacent die is five. If this case is substituted into FIG. 8A, it may be the case that M=5 and N=4.

The first group G1 according to an embodiment may be a group formed by grouping the first module, the second module, the third module, and the fourth module among the five modules of the connection module 5110a. The second group G2 according to an embodiment may be a group formed by grouping the second module, the third module, the fourth module, and the fifth module among the five modules of the connection module 5110a.

According to an embodiment, the multiple groups G1 and G2 may share the second module, the third module, and the fourth module. Therefore, the second module, the third module, and the fourth module commonly included in multiple groups G1 and G2 do not need to go through the selection circuit 5120a, and thus may be directly connected to the connection circuit 5130a without being connected to the selection circuit 5120a. That is, in order to select one of the multiple groups G1 and G2, only the first module included in the first group G1 and the fifth module included in the second group G2 may be connected to the selection circuit 5120a. According to an embodiment, because the second group G2 is selected to be aligned with the connection module 6110a included in the second die-to-die interface 6100, the selection circuit 5120a may output the fifth module.

According to the description given with reference to FIGS. 6A to 8B, the configuration of the selection circuit may be divided into three types. According to FIGS. 6A and 6B, a selection circuit that selects one group among a plurality of groups included in the connection module may be provided. According to FIGS. 7A and 7B, a selection circuit that selects some modules among a plurality of modules and configures one group that is aligned with the corresponding connection module may be provided. According to FIGS. 8A and 8B, a selection circuit that fixes some of the plurality of modules and selects only the remaining some modules to form the entire group may be provided.

While the above only discusses three types of selection circuits, the embodiment is not limited thereto. For example, various configurations of selection circuits capable of selecting some of a plurality of modules may be provided.

In an embodiment, each module within a chiplet die is equipped with physical or electronic markers such as notches, pins, or encoded data that identifies its position or function. These markers can be read by the selection circuit (e.g., 112a). As a chiplet is integrated into the system, the selection circuit scans for these markers to identify each module's characteristics and its physical or logical location relative to other modules.

In an embodiment, the selection circuit is powered by a software algorithm that processes data about each module's capabilities, such as speed, bandwidth, and electrical characteristics, to determine compatibility. Upon the activation or insertion of a new chiplet die, the system's controller (part of the selection circuit) runs the algorithm to evaluate which modules on the new die align best with the existing die's modules based on predetermined criteria.

In an embodiment, integrated sensors in each chiplet die detect physical alignment (via optical or contact sensors) or electronic signals (such as impedance, signal integrity tests) to determine the proximity and orientation of adjacent modules. Wen a chiplet is placed into the system, these sensors provide real-time feedback to the selection circuit, which then uses this information to activate the appropriate modules that meet the alignment criteria.

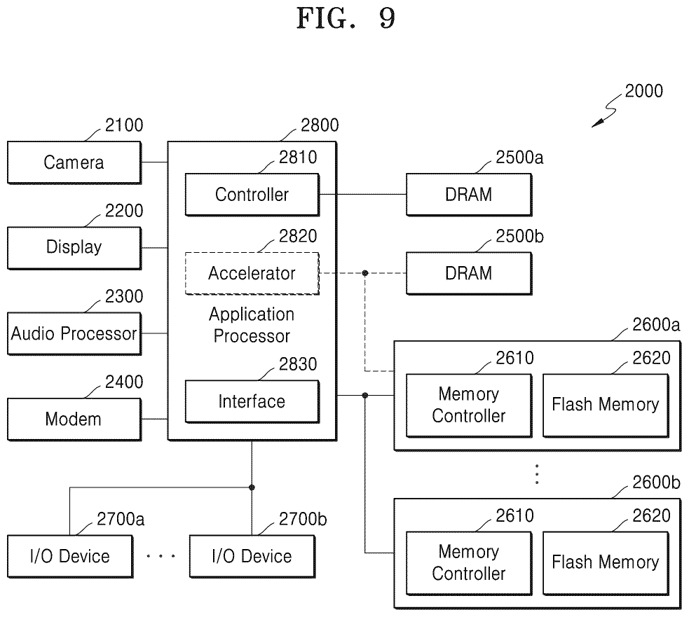

FIG. 9 is a block diagram of a system 2000 to explain an electronic device including a D2D interface according to embodiments.

Referring to FIG. 9, the system 2000 may include a camera 2100, a display 2200, an audio processor 2300, a modem 2400, DRAMs 2500a and 2500b, flash memories 2600a and 2600b, I/O devices 2700a and 2700b, and an application processor 2800 (hereinafter referred to as “AP”). The system 2000 may be implemented as a laptop computer, a mobile phone, a smart phone, a tablet personal computer, a wearable device, a healthcare device, or an Internet Of Things (IoT) device. In addition, the system 2000 may be implemented as a server or a personal computer.

The camera 2100 may capture still images or moving images according to the user's control, and may store the captured image/video data or transmit the captured image/video data to the display 2200. The audio processor 2300 may process audio data included in the contents of the flash memories 2600a and 2600b or a network. The modem 2400 may modulate and transmit a signal for wired/wireless data transmission and reception and may demodulate the signal at the receiving end to restore the original signal. The I/O devices 2700a and 2700b may include devices that provide digital input and/or output functions, such as, a Universal Serial Bus (USB), a storage, a digital camera, a Secure Digital (SD) card, a Digital Versatile Disc (DVD), a network adapter, a touch screen, etc.

The AP 2800 can control an overall operation of the system 2000. The AP 2800 may include a controller 2810, an accelerator 2820 or an accelerator chip 2820, and an interface 2830. The AP 2800 can control the display 2200 so that a part of the content stored in the flash memories 2600a and 2600b is displayed on the display 2200. The AP 2800 may perform a control operation corresponding to a user input when a user input is received through I/O devices 2700a and 2700b. The AP 2800 may include an accelerator block, which is a dedicated circuit for Artificial Intelligence (AI) data operation, or may have an accelerator chip 2820 separately from the AP 2800. A DRAM 2500b may be additionally mounted on the accelerator block or the accelerator chip 2820. The accelerator 2820 is a functional block that specifically performs a specific function of the AP 2800 and may include a GPU which is a functional block that specializes in processing graphic data, a Neural Processing Unit (NPU) which is a block that specializes in performing AI calculations and inference, and a Data Processing Unit (DPU) which is a block that specializes in data transmission.

The system 2000 may include multiple DRAMs 2500a and 2500b. The AP 2800 may control the DRAMs 2500a and 2500b through commands and mode register (MRS) settings that complies with the Joint Electron Device Engineering Council (JEDEC) standard specifications, or may communicate by setting a DRAM interface protocol to use a company's unique functions such as low voltage/high speed/reliability and Cyclic Redundancy Check (CRC)/Error Correction Code (ECC) functions. For example, the AP 2800 may communicate with DRAM 2500a with an interface that complies with JEDEC standard specifications such as LPDDR4 and LPDDR5, and the accelerator block or accelerator chip 2820 can communicate by setting a new DRAM interface specification to control the DRAM 2500b for an accelerator that has a higher bandwidth than the DRAM 2500a.

In FIG. 9, only the DRAMs 2500a and 2500b are illustrated, but the embodiment is not limited thereto, and any memory such as PRAM, SRAM, MRAM, RRAM, FRAM, or Hybrid RAM may be used as long as it satisfies the bandwidth, response speed, and voltage conditions of the AP 2800 or the accelerator chip 2820. The DRAMs 2500a and 2500b have relatively lower latency and bandwidth than the I/O devices 2700a and 2700b or the flash memories 2600a and 2600b. The DRAMs 2500a and 2500b may be used as a temporary storage location for an operating system and application data or as an execution space for various software codes by being initialized at a power-on time of the system 2000 and the operating system and application data are loaded.

In the DRAMs 2500a and 2500b, the four basic operations of addition/subtraction/multiplication/division, and vector operations, address operations, or Fast Fourier Transform (FFT) operations may be performed. In addition, a function for performing inference may be performed in the DRAMs 2500a and 2500b. Here, the inference may be performed in a deep learning algorithm using an artificial neural network. The deep learning algorithm may include a training operation for learning a model through various data and an inference operation for recognizing data with the learned model. As one embodiment, an image captured by the user through the camera 2100 is signal-processed and stored in the DRAM 2500b, and the accelerator block or the accelerator chip 2820 may perform an AI data operation that recognizes data using data stored in the DRAM 2500b and a function used for inference.

The system 2000 may include a plurality of storages or the plurality of flash memories 2600a and 2600b having a larger capacity than the DRAMs 2500a and 2500b. The accelerator block or the accelerator chip 2820 may perform a training operation and an AI data operation using the flash memories 2600a and 2600b. In an embodiment, the flash memories 2600a and 2600b include a memory controller 2610 and a flash memory device 2620 and may more efficiently perform the training operation and inference AI data operation performed by the AP 2800 and/or the accelerator chip 2820 by using an operation device provided in the memory controller 2610. The flash memories 2600a and 2600b may store images taken by the camera 2100 or data transmitted through a data network. For example, the flash memories 2600a and 2600b may store Augmented Reality/Virtual Reality, High Definition (HD) or Ultra High Definition (UHD) content.

In the system 2000, the AP 2800 and the DRAMs 2500a and 2500b may be interconnected via a D2D interface described with reference to the drawings described above. In addition, the memory controller 2610 and the flash memory device 2620 of the flash memories 2600a and 2600b may also be interconnected via the D2D interface. According to an embodiment, the D2D interface may enable the creation of an efficient chiplet die without the need for manufacturing a new chiplet die according to its arrangement structure, by including a die-to-die interface that allows for selection of variably aligned positions. According to an embodiment, an additional design may be performed from the perspective of a D2D configuration connecting a die and a die, and a chiplet die may be configured by selecting only the necessary modules among the modules.

While the inventive concept has been particularly shown and described with reference to embodiments thereof, it will be understood that various changes in form and details may be made therein without departing from the spirit and scope of the following claims.

What is claimed is:

1. A semiconductor device comprising:
a plurality of chiplet dies that are configurable as semiconductor chips; and
an interposer on which the plurality of chiplet dies are mounted,
wherein the plurality of chiplet dies each include a die-to-die interface for being connected to each other,
wherein the die-to-die interface comprises:
a first connection module included in a first chiplet die among the chiplet dies, the first connection module comprising a plurality of first modules;
a second connection module included in a second chiplet die among the chiplet dies, the second connection module comprising a plurality of second modules; and
a selection circuit configured to select one of the second modules that aligns with a corresponding one of the first modules.

2. The semiconductor device of claim 1, wherein a number of the first modules is different from a number of the second modules.

3. The semiconductor device of claim 2, wherein
the number of the second modules is an integer multiple of the number of the first modules.

4. The semiconductor device of claim 3, wherein a number of multiplexers included in the selection circuit is one.

5. The semiconductor device of claim 2, wherein
the number of the first modules is N, and
the number of the second modules is M,
wherein M is a value greater than N, and M and N are natural numbers.

6. The semiconductor device of claim 5, wherein a number of multiplexers included in the selection circuit is M−N+1.

7. The semiconductor device of claim 5, wherein
among the M second modules, A modules are fixed and aligned,
the selection circuit includes a multiplexer for connecting the remaining modules other than the A modules, and
A is a natural number, and A has a value less than M and N.

8. A semiconductor device comprising:
a first chiplet die including a first die-to-die interface; and
a second chiplet die including a second die-to-die interface,
wherein the first chiplet die and the second chiplet die are adjacent to each other,
wherein lengths of surfaces where the first chiplet die and the second chiplet die are adjacent to each other are different,
wherein the first die-to-die interface includes N modules for connecting to the second die, and the second die-to-die interface includes M modules for connecting to the first die,
wherein N is different from M, and N and M are natural numbers, and
wherein the second die-to-die interface includes a selection circuit configured to select one or more of the M modules that align with corresponding ones of the N modules.

9. The semiconductor device of claim 8, wherein the M modules include modules alignable with the N modules.

10. The semiconductor device of claim 8, wherein the M modules is an integer multiple of the N modules.

11. The semiconductor device of claim 8, wherein the selection circuit includes at least one multiplexer.

12. The semiconductor device of claim 8, wherein the selection circuit includes one multiplexer for selecting, from among the M modules, a group corresponding to the N modules.

13. The semiconductor device of claim 8, wherein the selection circuit includes M-N+1 multiplexers for selecting, from among the M modules, sequential groups corresponding to the N modules.

14. The semiconductor device of claim 8, wherein the selection circuit includes a multiplexer for selecting the remaining modules other than modules that are fixedly provided among the M modules.

15. A semiconductor device comprising:
a plurality of chiplet dies that are configurable as semiconductor chips; and
an interposer on which the plurality of chiplet dies are mounted,
wherein the plurality of chiplet dies each include a die-to-die interface for being connected to each other,
a first die-to-die interface included in a first chiplet die includes N modules, and
a second die-to-die interface included in a second chiplet die includes M modules,
wherein the N modules are configured to connect all of the N modules to another die, and
the M modules are configured to connect only some of the M modules among the M modules to another die, and N and M are natural numbers.

16. The semiconductor device of claim 15, wherein the second die-to-die interface further includes a selection circuit for selecting some of the M modules.

17. The semiconductor device of claim 16, wherein the selection circuit includes at least one multiplexer.

18. The semiconductor device of claim 17, wherein the selection circuit includes one multiplexer for selecting, from among the M modules, a group corresponding to the N modules.

19. The semiconductor device of claim 17, wherein
the selection circuit includes M−N+1 multiplexers for selecting, from among the M modules, a sequential group corresponding to the N modules.

20. The semiconductor device of claim 17, wherein
the selection circuit includes a multiplexer for selecting the remaining modules other than modules that are fixedly provided among the M modules.
